(19) United States
(12) Patent Application Publication
(10) Pub. No.: US 2015/0380535 A1
(43) Pub. Date: Dec. 31, 2015

(54) SEMICONDUCTOR DEVICE

(71) Applicant: Kabushiki Kaisha Toshiba, Tokyo (JP)

(72) Inventors: Yuuichi Oshino, Tokyo (JP); Tsuneo Ogura, Kanagawa (JP)

(21) Appl. No.: 14/639,545

(22) Filed: Mar. 5, 2015

(30) Foreign Application Priority Data
Jun. 27, 2014 (JP) 2014-132960

(51) Int. Cl. H01L 29/739; H01L 29/10; H01L 29/36; H01L 29/423

(52) U.S. Cl. CPC H01L 29/7397; H01L 29/4236; H01L 29/1095; H01L 29/36

(57) ABSTRACT

According to one embodiment, a semiconductor device includes a first semiconductor region, a second semiconductor region, a third semiconductor region, a fourth semiconductor region, a fifth semiconductor region, and a gate electrode. The length in a first direction of a portion of the gate electrode opposing the third semiconductor region being longer than a length in the first direction of a portion of the gate electrode opposing the fifth semiconductor region. An impurity concentration of the second conductivity type of the fourth semiconductor region is higher than an impurity concentration of the second conductivity type of an intermediate portion in the third semiconductor region. At least a part of the intermediate portion is arranged with a part of the first insulating region in the third direction. At least a part of the fifth semiconductor region is not arranged with the first insulating region in the third direction.

### CROSS-REFERENCE TO RELATED APPLICATIONS

This application is based upon and claims the benefit of priority from Japanese Patent Application No.2014-132960, filed on Jun. 27, 2014; the entire contents of which are incorporated herein by reference.

### FIELD

Embodiments described herein relate generally to a Semiconductor device.

### BACKGROUND

Semiconductor devices such as, for example, insulated gate bipolar transistors (called IGBTs below), etc., are used as switching elements in electronic devices and the like.

It is desirable for such a semiconductor device to have a structure more suitable for mass production.

### BRIEF DESCRIPTION OF THE DRAWINGS

FIG. 1 is a cross-sectional view of a semiconductor device according to a first embodiment;

FIG. 2 is a plan view of the semiconductor device according to the first embodiment;

FIGS. 3A-3E are cross-sectional views of processes, showing manufacturing processes of the semiconductor device according to the first embodiment;

FIGS. 4A-4E are cross-sectional views of processes, showing manufacturing processes of the semiconductor device according to the first embodiment; and

FIG. 5 is a cross-sectional view of a semiconductor device according to a second embodiment.

### DETAILED DESCRIPTION

In general, according to one embodiment, a semiconductor device includes a first semiconductor region of a second conductivity type, a second semiconductor region of a first conductivity type, a third semiconductor region of the second conductivity type, a fourth semiconductor region of the second conductivity type, a fifth semiconductor region of the first conductivity type, and a gate electrode. The second semiconductor region is provided on the first semiconductor region. The third semiconductor region is provided on the second semiconductor region. The fifth semiconductor region is provided on the third semiconductor region. The gate electrode provided in the third semiconductor region with a first insulating region interposed. The first insulating region contacts the fifth semiconductor region. The length in a first direction of a portion of the gate electrode opposing the third semiconductor region with the first insulating region interposed being longer than a length in the first direction of a portion of the gate electrode opposing the fifth semiconductor region with the first insulating region interposed. The first direction is perpendicular to a third direction which is from the third semiconductor region toward the second semiconductor region. The fourth semiconductor region of the second conductivity type is selectively provided on the third semiconductor region. An impurity concentration of the second conductivity type of the fourth semiconductor region is higher than an impurity concentration of the second conductivity type of an intermediate portion in the third semiconductor region. The intermediate portion is positioned between the fourth semiconductor region and the fifth semiconductor region. At least a part of the intermediate portion is arranged with a part of the first insulating region in the third direction. At least a part of the fifth semiconductor region is not arranged with the first insulating region in the third direction.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

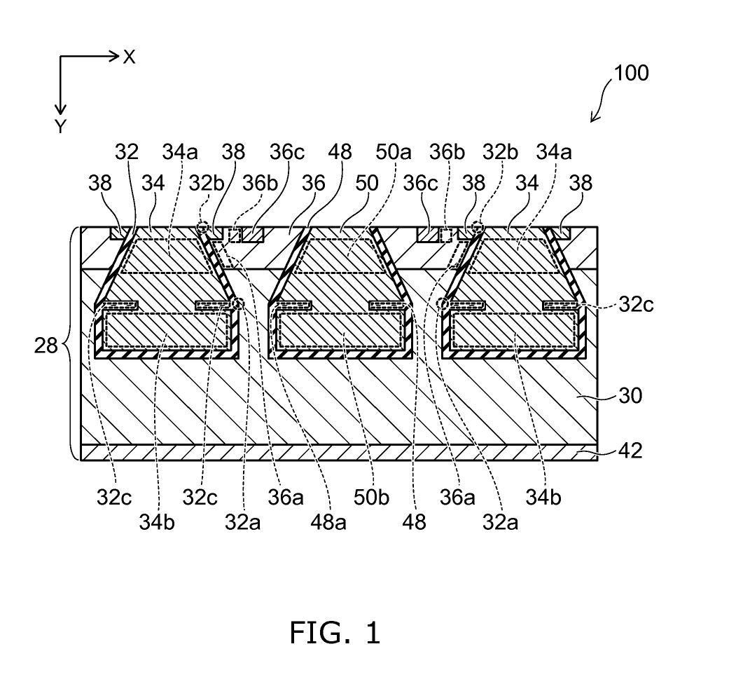

FIG. 1 is a cross-sectional view of a semiconductor device according to a first embodiment.

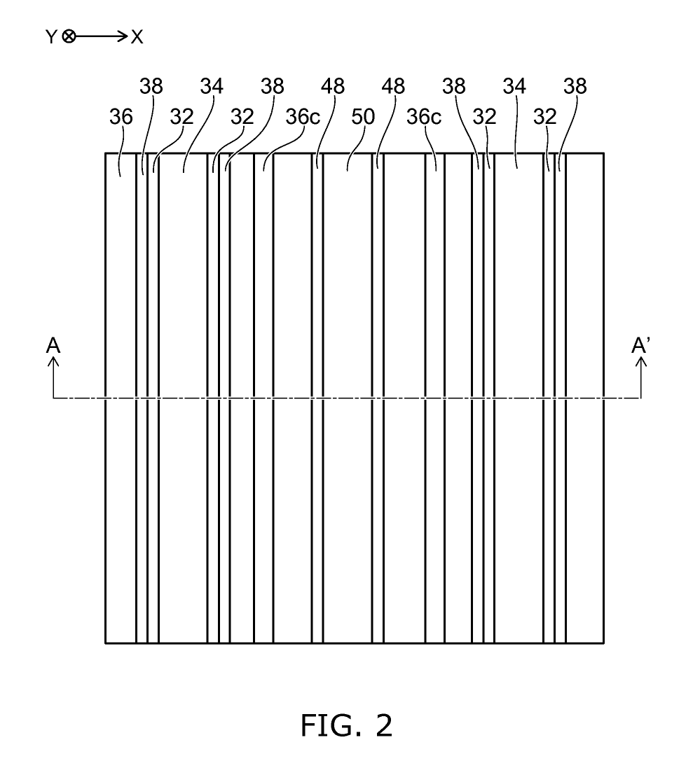

FIG. 2 is a plan view of the semiconductor device according to the first embodiment.

FIG. 1 is an A-A′ cross-sectional view of FIG. 2.

The case where the first conductivity type is an n-type and the second conductivity type is a p-type is described in the embodiment. However, the first conductivity type may be the p-type; and the second conductivity type may be the n-type.

The semiconductor device 100 is, for example, an IGBT. As shown in FIG. 1, the semiconductor device 100 includes a semiconductor substrate 28 (hereinbelow, called simply the substrate 28). The substrate 28 is, for example, a silicon substrate.

The substrate 28 includes an n-base region 30 (a second semiconductor region) of the first conductivity type, a p-base region 36 (a third semiconductor region) of the second conductivity type that is selectively provided on the n-base region 30, and an emitter region 38 (a fifth semiconductor region) of the first conductivity type that is selectively provided on the p-base region 36.

The p-base region 36 includes a first region 36a, a second region 36b, and a third region 36c (a fourth semiconductor region).

The first region 36a exists to be aligned with a first insulating region 32 that is described below. The first region 36a exists between the n-base region 30 and the emitter region 38.

The impurity concentration of the second conductivity type of the third region 36c is higher than the impurity concentration of the second conductivity type of the first region 36a and the impurity concentration of the second conductivity type of the second region 36b. For example, the third region 36c is provided to efficiently discharge the carriers (the holes) of the second conductivity type.

The third region 36c is formed by, for example, forming a semiconductor region (the p-base region 36) of the second conductivity type on the n-base region 30 and by further performing ion implantation of an impurity of the second conductivity type into a prescribed region inside the semiconductor region.

The substrate 28 includes a collector region 42 (a first semiconductor region) of the second conductivity type provided on the side opposite to the p-base region 36; and the n-base region 30 is positioned between the p-base region 36 and the collector region 42. In other words, in the case where the direction of the p-base region 36 from the n-base region 30 is taken to be up, the collector region 42 is provided under the n-base region 30.

A not-shown emitter electrode is provided on the side of the substrate 28 where the emitter region 38 is provided; and the emitter electrode is connected to the emitter region 38. A not-shown collector electrode is provided on the side of the substrate 28 where the collector region 42 is provided; and the collector electrode is connected to the collector region 42.

The substrate 28 further includes a gate electrode (a first gate electrode) 34 that is separated from the semiconductor region by the first insulating region 32, and an electrode 50 that is separated from the semiconductor region by a second insulating region 48. The gate electrode 34 and the electrode 50 are provided to be arranged alternately. A portion of the gate electrode 34 is provided in the p-base region 36 with the first insulating region 32 interposed. A portion of the electrode 50 is provided in the p-base region 36 with the second insulating region 48 interposed. The gate electrode 34 and the electrode 50 are provided so that a portion of the n-base region 30, the p-base region 36, and at least a portion of the emitter region 38 are interposed between the gate electrode 34 and the electrode 50.

The gate electrode 34 and the electrode 50 may be formed by making trenches in the substrate 28 and filling an electrode material into the trenches with an insulating film interposed. For example, polysilicon is used as the material of the gate electrode 34 and the electrode 50. For example, silicon oxide is used as the material of the first insulating region 32 and the second insulating region 48.

By applying a voltage to the gate electrode 34, a channel (an inversion layer) for the carriers (the electrons) of the first conductivity type is formed in the first region 36a at the first insulating region 32 vicinity. The electrode 50 is connected to, for example, an emitter electrode. In such a case, for example, the electrode 50 is connected to a fixed potential. The ground potential is an example of the fixed potential. In the case where the electrode 50 is connected to the fixed potential, the electrode 50 may function as a field plate electrode.

As shown in FIG. 2, the emitter region 38 of the first conductivity type is provided in the p-base region 36 front surface to contact the first insulating region 32. The third region 36c is provided in the p-base region 36 front surface to be positioned at substantially the middle between the first insulating region 32 and the second insulating region 48. However, the third region 36c may be provided to spread from the middle position between the first insulating region 32 and the second insulating region 48 toward the second insulating region 48 side.

The impurity concentrations of the semiconductor regions are as follows. The values of the impurity concentrations are the impurity concentrations of the conductivity types after the impurity of the first conductivity type and the impurity of the second conductivity type are mutually compensated.

The impurity concentration of the n-base region 30 is 5.0×10¹² to 2.0×10¹⁴ atoms/cm³.

The peak impurity concentration of the first region 36a of the p-base region 36 is 5.0×10¹⁶ to 5.0×10¹⁷ atoms/cm³.

The peak impurity concentration of the third region 36c of the p-base region 36 is not less than 1.0×10¹⁹ atoms/cm³.

The peak impurity concentration of the emitter region 38 is not less than 1.0×10¹⁹ atoms/cm³.

The impurity concentration of the emitter region 38 is higher than the impurity concentrations of the n-base region 30 and the first region 36a.

The impurity concentration of the collector region 42 is 1.0×10¹⁶ to 1.0×10¹⁹ atoms/cm³.

The impurity concentration of the collector region 42 is higher than the impurity concentration of the n-base region 30.

Here, the direction from the emitter region 38 toward the third region 36c is taken as a first direction; and the direction from the third region 36c toward the emitter region 38 is taken as a second direction. In the semiconductor device 100 according to the embodiment, the emitter region 38 is provided further on the second-direction side than is a first end portion 32a positioned at the first-direction end of the first insulating region 32. In other words, when viewed in plan, the emitter region 38 is provided between the first end portion 32a and a second end portion 32b of the upper end of the first insulating region 32, where the second end portion 32b is the first-direction end of the upper end that contacts the semiconductor region.

It can be determined whether or not the emitter region 38 is provided further on the second-direction side than is the first end portion 32a by, for example, determining whether or not the junction surface between the emitter region 38 and the p-base region 36 is provided further on the second-direction side than is the first end portion 32a.

The first direction is, for example, the X-direction of FIG. 1. However, the first direction may be the direction opposite to the X-direction according to the positional relationship between the emitter region 38 and the third region 36c.

In the semiconductor device 100 according to the embodiment, the gate electrode 34 includes a first portion 34a opposing the n-base region 30, the p-base region 36, and the emitter region 38. In the first portion 34a, the length in the first direction of the portion opposing the p-base region 36 with the first insulating region 32 interposed is longer than the length in the first direction of the portion opposing the emitter region 38 with the first insulating region 32 interposed. In other words, the first portion 34a has a tapered configuration in which the length in the first direction gradually increases from the upper portion toward the lower portion over the depth from the lower end of the emitter region 38 to the lower end of the p-base region 36.

To improve the suitability for mass production of the semiconductor device, it is desirable to downscale the element size and increase the number of elements that can be made in one wafer. On the other hand, in the case where the element size is small, the impurity of the second conductivity type undesirably diffuses to the vicinity of the first region 36a when forming the third region 36c; and the threshold of the gate electrode 34 undesirably fluctuates.

To avoid such a problem, it may be considered to perform ion implantation of a high concentration of the impurity of the second conductivity type into a micro region separated from the first region 36a when forming the third region 36c. However, in such a case, the resistance of the p-base region 36 is not reduced sufficiently; and problems occur easily such as latchup of the parasitic transistor formed from the n-base region 30, the p-base region 36, and the emitter region 38.

Conversely, in the case where the emitter region 38 is provided on the second-direction side of the first end portion 32a, the holes from the collector region 42 toward the p-base region 36 do not easily pass on the second-direction side of the first end portion 32a. In other words, most of the holes pass on the first-direction side of the first end portion 32a.

As a result, the occurrence of the latchup of the parasitic transistor formed from the n-base region 30, the p-base region 36, and the emitter region 38 can be suppressed because the holes do not easily pass through the vicinity of the emitter region 38.

It is favorable for the third region 36c to be provided on the first-direction side of the first end portion 32a. In such a case, when viewed in plan, the first end portion 32a is positioned between the emitter region 38 and the third region 36c; and the second region 36b that has a lower impurity concentration of the second conductivity type than the third region 36c is positioned at a position overlapping the first end portion 32a.

In other words, at least a part of the second region 36b is arranged with a part of the first insulating region 32 in the third direction. At least a part of the third region 36c is not arranged with the first insulating region 32 in the third direction.

The holes that pass through the p-base region 36 pass even less easily through the first region 36a because the third region 36c is provided on the first-direction side of the first end portion 32a.

Although the second region 36b and the third region 36c are formed separately in the description of the embodiment, the second region 36b and the third region 36c may be provided as one impurity region of the second conductivity type. In such a case, the impurity region of the second conductivity type has a concentration gradient between the second region 36b and the third region 36c in which the impurity concentration of the second conductivity type increases toward the first direction.

To further improve the suitability for mass production of the semiconductor device, it is desirable for the depth of the impurity region, e.g., the p-base region 36, that is formed in the substrate 28 to be shallow. By setting the depth of the impurity region to be shallow, the time necessary for the ion implantation of the impurity and the heat treatment time after the ion implantation can be shortened. By shortening the processing time, the number of processed wafers per unit time increases; and the productivity increases.

However, in the case where the p-base region 36 is set to be shallow, the distance (the length of the first region 36a) between the n-base region 30 and the emitter region 38 is shorter. In the case where the distance between the n-base region 30 and the emitter region 38 is short, the likelihood becomes high that movement of the carriers between the n-base region 30 and the emitter region 38 may occur at a voltage that is the threshold of the gate electrode 34 or less.

Conversely, by the gate electrode 34 including the first portion 34a, the gate electrode 34 crosses the p-base region 36 obliquely with respect to the depth direction of the substrate 28. Accordingly, compared to the case where the gate electrode 34 crosses the p-base region 36 in the depth direction of the substrate 28, the distance between the n-base region 30 and the emitter region 38, that is, the channel length, can be lengthened. As a result, even in the case where the p-base region 36 is shallow, it is possible to suppress the movement of the carriers between the n-base region 30 and the emitter region 38 at a voltage that is the threshold of the gate electrode 34 or less.

In the semiconductor device according to the embodiment, the gate electrode 34 includes a second portion 34b that is positioned below the first portion 34a. The second portion 34b extends in a third direction from the p-base region 36 toward the n-base region 30.

The third direction is, for example, the Y-direction of FIG. 1.

By setting the second portion 34b to extend in the third direction, the carrier accumulation amount of the n-base region 30 is increased; and the on-voltage of the semiconductor device 100 can be reduced by the IE (Injection Enhanced) effect. As a result, it is possible to suppress the degradation of the characteristics when downscaling the element.

Here, it is possible to further reduce the element size by the amount that the characteristics of the semiconductor device are improved. Therefore, by the amount that the on-voltage can be reduced by the second portion 34b, the element can be downscaled further; and the suitability of the semiconductor device for mass production can be improved.

It is favorable for the third direction in which the second portion 34b extends to be a direction orthogonal to the first direction. In the case where the second portion 34b has a tapered configuration similar to that of the first portion 34a, it is difficult to provide the spacing to the adjacent electrode 50 when extending the second portion 34b in the depth direction (the third direction); and the second portion 34b cannot be extended to a deep depth. By setting the direction in which the second portion 34b extends to be a direction orthogonal to the first direction, it is possible to extend the second portion 34b to a deeper region while maintaining the spacing to the adjacent electrode 50. In other words, it is possible to provide the gate electrode 34 to a deeper region. By providing the gate electrode 34 to the deeper region, the IE effect is increased further; and it is possible to reduce the on-voltage of the semiconductor device 100.

The first insulating region 32 may include a portion 32c that extends toward the gate electrode 34 interior. At least a portion of the portion 32c is positioned between the first portion 34a and the second portion 34b.

Similarly to the gate electrode 34, the electrode 50 includes a first portion 50a and a second portion 50b.

In a region opposing the p-base region 36, the length in the first direction of the first portion 50a on the n-base region 30 side is longer than the length in the first direction of the first portion 50a on the p-base region 36 side. In other words, the first portion 50a has a tapered configuration in which the length in the first direction gradually increases toward the third direction.

The second portion 50b is positioned below the first portion 50a and extends in the third direction.

The second insulating region 48 may include a portion 48a extending toward the electrode 50 interior. A portion of the portion 48a is positioned between the first portion 50a and the second portion 50b.

It is possible to make the electrode 50 and the second insulating region 48 simultaneously with the gate electrode 34 and the first insulating region 32 because, similarly to the gate electrode 34, the electrode 50 includes the first portion 50a and the second portion 50b and the second insulating region 48 includes the portion 48a.

However, the electrode 50 may not include the portions corresponding to the first portion 50a and the second portion 50b; and the electrode 50 may be, for example, an electrode that extends uniformly only in the third direction.

An example of the method for manufacturing the semiconductor device 100 according to the first embodiment will now be described.

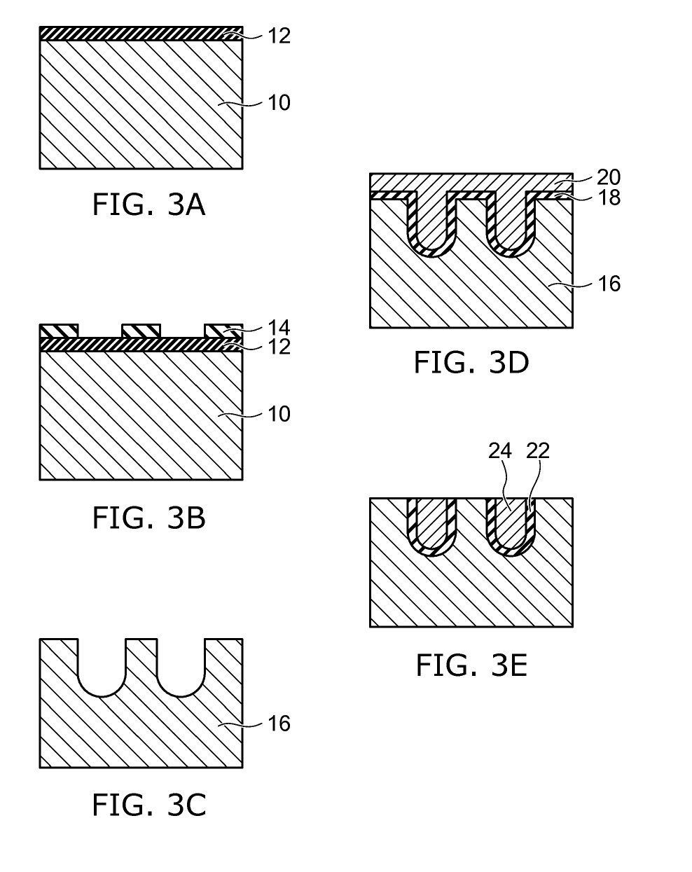

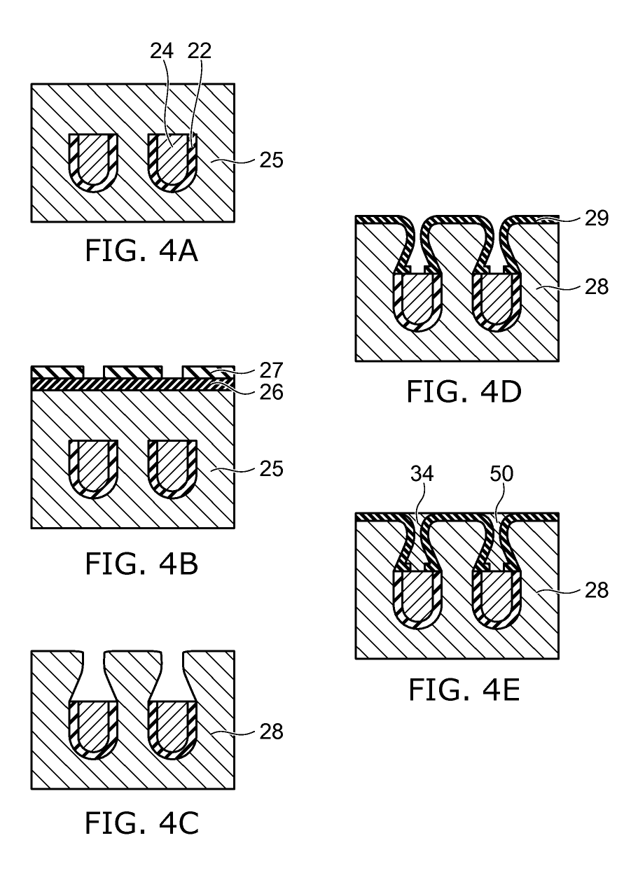

FIG. 3 and FIG. 4 are cross-sectional views of processes, showing manufacturing processes of the semiconductor device according to the first embodiment.

A silicon oxide film 12 is formed on a semiconductor substrate 10 of the first conductivity type (FIG. 3A).

A patterned photoresist 14 is formed on the silicon oxide film 12 (FIG. 3B).

The silicon oxide film 12 is patterned using the photoresist 14 as a mask. Anisotropic etching is performed using the patterned silicon oxide film 12 as a hard mask. A semiconductor substrate 16 is made in this process so that trenches are made in the semiconductor substrate 16 (FIG. 3C).

A silicon oxide film 18 and a polysilicon film 20 are formed on the semiconductor substrate 16 (FIG. 3D).

CMP and dry etching are performed to remove the silicon oxide film 18 and the polysilicon film 20 that are formed on the semiconductor substrate 10 other than the silicon oxide film 18 and the polysilicon film 20 that are formed in the trench interiors. A silicon oxide film 22 and a polysilicon film 24 are formed in the trench interiors in this process (FIG. 3E).

A semiconductor substrate 25 is made by performing epitaxial growth of a semiconductor layer on the semiconductor substrate 16 so that the silicon oxide film 22 and the polysilicon film 24 are provided in the interior of the semiconductor substrate 25 (FIG. 4A). It is favorable for the material of the epitaxial growth to be the same as that of the semiconductor substrate 16. It is favorable for the layer that is epitaxially grown to have an impurity concentration similar to that of the semiconductor substrate 16.

A silicon oxide film 26 and a patterned photoresist 27 are formed on the semiconductor substrate 25 (FIG. 4B).

The silicon oxide film 26 is patterned using the photoresist 27 as a mask. The semiconductor substrate 28 is made by performing anisotropic etching of the semiconductor substrate 25 using the patterned silicon oxide film so that trenches are formed in the semiconductor substrate 28 (FIG. 4C). At this time, each trench is made to have a tapered configuration in which the length in the first direction gradually increases toward the third direction by adjusting the gas atmosphere of the anisotropic etching, the electrical power that is provided, the pressure of the processing space, and the processing time.

A silicon oxide film 29 is formed on the semiconductor substrate 28. The silicon oxide film 29 at the trench bottom is removed by anisotropic etching to electrically connect the already-formed polysilicon film 24 to a polysilicon film to be formed subsequently (FIG. 4D). At this time, the silicon oxide film 29 that is positioned at the outer circumference of the trench bottom may not be removed and may remain. A silicon oxide film 31 that is not removed and remains to be positioned at the outer circumference of the trench bottom corresponds to the portion 32c of the first insulating region 32 and the portion 48a of the second insulating region 48.

The gate electrode 34 and the electrode 50 are formed by forming the polysilicon film on the semiconductor substrate 28 and by removing the unnecessary portions (FIG. 4E).

Subsequently, the p-base region 36, the emitter region 38, and the collector region 42 are formed by performing ion implantation of an impurity into prescribed regions of the semiconductor substrate 28; and the semiconductor device 100 shown in FIG. 1 is made. The n-base region 30 is, for example, the region of the semiconductor substrate 28 other than the p-base region 36, the emitter region 38, and the collector region 42.

### Second Embodiment

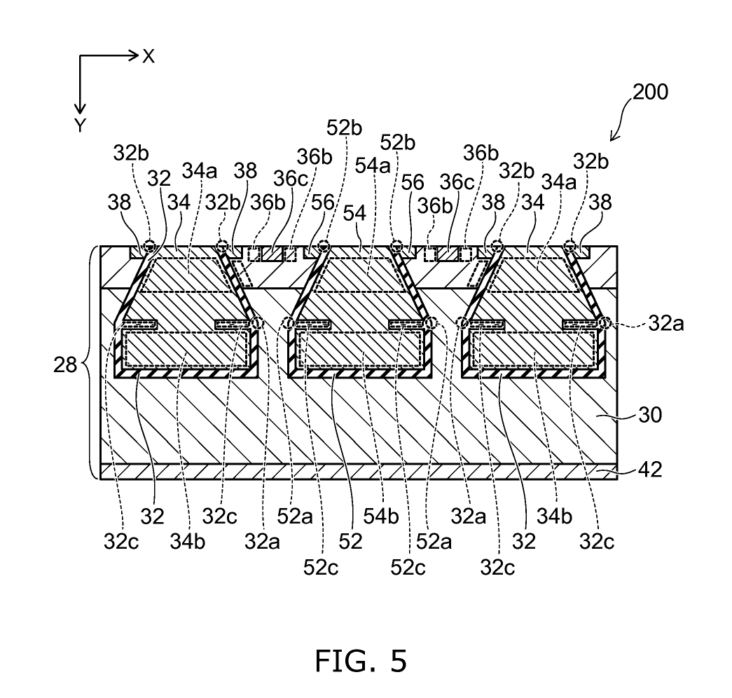

FIG. 5 is a cross-sectional view of a semiconductor device according to a second embodiment.

As shown in FIG. 5, the embodiment differs from the first embodiment in that a second gate electrode 54 is provided to be adjacent to the first gate electrode 34, and an emitter region 56 (the fifth semiconductor region) is provided. The emitter region 56 is provided at the vicinity of the second gate electrode 54 on the p-base region 36.

The second gate electrode 54 is separated from the semiconductor region by a second insulating region 52. A portion of the second gate electrode 54 is provided in the p-base region 36 with the second insulating region 52 interposed. By applying a voltage to the second gate electrode 54, a channel (an inversion layer) for the carriers (the electrons) of the first conductivity type is formed in the region at the second insulating region 52 vicinity.

The first gate electrode 34 and the second gate electrode 54 may have the same configuration and function.

Here, the direction from the emitter region 38 toward the third region 36c is taken to be the first direction; and the direction from the third region 36c toward the emitter region 38 is taken to be the second direction.

The emitter region 38 is provided on the second-direction side of the first end portion 32a which is positioned at the first-direction end of the first insulating region 32.

The emitter region 56 is provided on the first-direction side of a first end portion 52a which is positioned at the second-direction end of the second insulating region 52.

The first direction is, for example, the X-direction of FIG. 5. However, the first direction may be the direction opposite to the X-direction according to the positional relationship between the emitter region 38 and the third region 36c.

The second gate electrode 54 includes a first portion 54a, and a second portion 54b that is positioned below the first portion 54a. The first portion 54a is provided so that the length in the first direction of the portion of the first portion 54a opposing the p-base region 36 with the second insulating region 52 interposed is longer than the length in the first direction of the portion of the first portion 54a opposing the emitter region 38 with the second insulating region 52 interposed.

The first portion 54a has a tapered configuration in which the length in the first direction gradually increases toward the third direction. The second portion 54b extends in the second direction.

The second direction is, for example, the Y-direction of FIG. 5.

The second insulating region 52 may include a first portion 52c extending toward the second gate electrode 54 interior. A portion of the first portion 52c is positioned between the first portion 54a and the second portion 54b.

By the emitter region 56 being provided on the first-direction side of the first end portion 52a, the holes from the collector region 42 toward the p-base region 36 do not easily pass on the first-direction side of the first end portion 52a.

Therefore, the occurrence of the latchup of the parasitic transistor formed from the n-base region 30, the p-base region 36, and the emitter region 56 can be suppressed.

By the second gate electrode 54 including the first portion 54a, the gate electrode 54 crosses the p-base region 36 obliquely with respect to the depth direction of the substrate 28. Therefore, even in the case where the p-base region 36 is shallow, it is possible to suppress the movement of the carriers between the n-base region 30 and the emitter region 38 at a voltage that is not more than the threshold of the gate electrode 34.

By the second portion 54b extending in the second direction, it is possible to increase the carrier accumulation amount of the n-base region 30 and reduce the on-voltage.

According to the embodiment, it is possible to increase the density of the element compared to the first embodiment because the second gate electrode 54 is provided.

A carrier concentration of each semiconductor region is proportionate to an impurity concentration of each semiconductor region. So relative levels of impurity concentrations in the semiconductor regions described above can be understood as relative levels of carrier concentrations in the semiconductor regions.

The relative levels of the impurity concentrations of the semiconductor regions described above in the embodiments can be confirmed by using, for example, a SCM (scanning capacitance microscope).

An amount of impurity in each semiconductor region can be measured by, for example, a SIMS (scanning ion mass spectrometry).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor device, comprising:
a first semiconductor region of a second conductivity type;
a second semiconductor region of a first conductivity type provided on the first semiconductor region;
a third semiconductor region of the second conductivity type provided on the second semiconductor region;
a fifth semiconductor region of the first conductivity type selectively provided on the third semiconductor region;
a gate electrode provided in the third semiconductor region with a first insulating region interposed, the first insulating region contacting the fifth semiconductor region, a length in a first direction of a portion of the gate electrode opposing the third semiconductor region with the first insulating region interposed being longer than a length in the first direction of a portion of the gate electrode opposing the fifth semiconductor region with the first insulating region interposed, the first direction being perpendicular to a third direction which is from the third semiconductor region toward the second semiconductor region; and
a fourth semiconductor region of the second conductivity type selectively provided on the third semiconductor region, an impurity concentration of the second conductivity type of the fourth semiconductor region being higher than an impurity concentration of the second conductivity type of an intermediate portion in the third semiconductor region, the intermediate portion positioned between the fourth semiconductor region and the fifth semiconductor region, at least a part of the intermediate portion arranged with a part of the first insulating region in the third direction, at least a part of the fifth semiconductor region not arranged with the first insulating region in the third direction.

2. The device according to claim 1, wherein
the gate electrode includes a first portion and a second portion, the first portion being where the length in the first direction of the portion opposing the third semiconductor region with the first insulating region interposed is longer than the length in the first direction of the portion opposing the fifth semiconductor region with the first insulating region interposed, the second portion being positioned on the first semiconductor region side of the first portion, and
the second portion extends in a third direction from the second semiconductor region toward the first semiconductor region.

3. The device according to claim 2, wherein a length in the first direction of the second portion is longer than a length in the first direction of the first portion.

4. The device according to claim 2, wherein
the first insulating region includes a first portion extending toward the gate electrode, and
at least a portion of the first portion of the first insulating region is positioned between the first portion and the second portion of the gate electrode.

5. The device according to claim 1, further comprising a first electrode provided in the third semiconductor region with a second insulating region interposed,
the third semiconductor region and the fifth semiconductor region being provided between the gate electrode and the first electrode.

6. The device according to claim 5, wherein the first electrode includes a first portion in a region opposing the third semiconductor region, a length in the first direction of the first portion on the second semiconductor region side being longer than a length in the first direction of the first portion on the third semiconductor region side.

7. The device according to claim 5, wherein
the first electrode includes a first portion and a second portion, the first portion being where a length in the first direction of a portion of the first electrode opposing the third semiconductor region with the second insulating region interposed is longer than a length in the first direction of a portion of the first electrode opposing the fifth semiconductor region with the second insulating region interposed, the second portion being positioned on the first semiconductor region side of the first portion, and
the second portion of the first electrode extends in a third direction from the second semiconductor region toward the first semiconductor region.

8. The device according to claim 7, wherein
the second insulating region includes a first portion extending toward the first electrode, and
at least a portion of the first portion of the second insulating region is positioned between the first portion and the second portion of the first electrode.

9. The device according to claim 5, further comprising a sixth semiconductor region of the first conductivity type provided on the third semiconductor region to contact the second insulating region.

10. The device according to claim 9, wherein an carrier concentration of the first conductivity type of the sixth semiconductor region is higher than the carrier concentration of the second conductivity type of the third semiconductor region.

11. The device according to claim 5, wherein the first electrode is connected to a ground potential.

12. The device according to claim 1, wherein a carrier concentration of the first conductivity type of the fifth semiconductor region is higher than the carrier concentration of the second conductivity type of the third semiconductor region.

13. The device according to claim 1, wherein a carrier concentration of the first conductivity type of the fifth semiconductor region is higher than the carrier concentration of the first conductivity type of the second semiconductor region.

14. The device according to claim 1, wherein a carrier concentration of the second conductivity type of the first semiconductor region is higher than the carrier concentration of the first conductivity type of the second semiconductor region.
